(19) United States
(12) Patent Application Publication
(10) Pub. No.: US 2020/0381557 A1
(43) Pub. Date: Dec. 3, 2020

(54) SEMICONDUCTOR DEVICE AND SEMICONDUCTOR MEMORY DEVICE

(71) Applicant: Kioxia Corporation, Tokyo (JP)

(72) Inventors: Shigeki HATTORI, Kawasaki Kanagawa (JP); Tomomasa UEDA, Yokohama Kanagawa (JP); Keiji IKEDA, Kawasaki Kanagawa (JP)

(73) Assignee: Kioxia Corporation, Tokyo (JP)

(21) Appl. No.: 16/809,199

(22) Filed: Mar. 4, 2020

(30) Foreign Application Priority Data
May 31, 2019 (JP) 2019-102530

(51) Int. Cl. H01L 29/786; H01L 27/108

(52) U.S. Cl. CPC H01L 29/7869; H01L 27/10891

(57) ABSTRACT

According to an embodiment, a semiconductor device includes an oxide semiconductor layer including indium (In), aluminum (Al), and zinc (Zn), the oxide semiconductor layer having an atomic ratio of the aluminum to a sum of indium, aluminum, and zinc of equal to or more than 8% and equal to or less than 23%, a gate electrode, and a gate insulating layer provided between the oxide semiconductor layer and the gate electrode.

### CROSS-REFERENCE TO RELATED APPLICATION

This application is based upon and claims the benefit of priority from Japanese Patent Application No. 2019-102530, filed on May 31, 2019, the entire contents of which are incorporated herein by reference.

### FIELD

Embodiments described herein relate generally to a semiconductor device and a semiconductor memory device.

### BACKGROUND

An oxide semiconductor transistor in which an oxide semiconductor layer is used as a channel layer has an excellent characteristic in that a channel leakage current during an OFF operation is very small. Therefore, for example, it is examined that the oxide semiconductor transistor is applied to as a switching transistor of a memory cell in a dynamic random access memory (DRAM).

When the oxide semiconductor transistor is applied as the switching transistor of the memory cell, the oxide semiconductor transistor is subjected to heat treatment accompanied with formation of the memory cell or a wiring. Thus, it is expected to realize an oxide semiconductor transistor which has high heat resistance and small fluctuation in characteristics even after the heat treatment.

### BRIEF DESCRIPTION OF THE DRAWINGS

FIG. 1 is a schematic sectional view illustrating a semiconductor device according to a first embodiment;

FIG. 2 is a diagram illustrating functions and effects of the semiconductor device in the first embodiment;

FIG. 3 is a diagram illustrating the functions and effects of the semiconductor device in the first embodiment;

FIG. 4 is a schematic sectional view illustrating a semiconductor device according to a second embodiment;

FIG. 5 is a schematic sectional view illustrating the semiconductor device in the second embodiment;

FIG. 6 is a schematic sectional view illustrating a semiconductor device according to a third embodiment;

FIG. 7 is a schematic sectional view illustrating the semiconductor device in the third embodiment;

FIG. 8 is a block diagram illustrating a semiconductor memory device according to a fourth embodiment;

FIG. 9 is a schematic sectional view illustrating a memory cell array in the semiconductor memory device in the fourth embodiment;

FIG. 10 is a schematic sectional view illustrating the memory cell array in the semiconductor memory device in the fourth embodiment;

FIG. 11 is a schematic sectional view illustrating a first memory cell in the semiconductor memory device in the fourth embodiment; and

FIG. 12 is a schematic sectional view illustrating a second memory cell in the semiconductor memory device in the fourth embodiment.

### DETAILED DESCRIPTION

According to an embodiment, a semiconductor device includes an oxide semiconductor layer including indium (In), aluminum (Al), and zinc (Zn), the oxide semiconductor layer having an atomic ratio of the aluminum to a sum of indium, aluminum, and zinc of equal to or more than 8% and equal to or less than 23%, a gate electrode, and a gate insulating layer provided between the oxide semiconductor layer and the gate electrode.

Hereinafter, embodiments of the present disclosure will be described with reference to the drawings. In the following descriptions, the same or similar members and the like are denoted by the same reference signs, and descriptions of members which are described once will be omitted as appropriate.

In this specification, the term of “upper” or “lower” may be used for convenience. The term of “upper” or “lower” is a term indicating a relative positional relationship in the drawings, and not defining a positional relationship with respect to gravity.

In this specification, for example, secondary ion mass spectroscopy (SIMS), energy dispersive X-ray spectroscopy (EDX), or Rutherford back-scattering spectroscopy (RBS) may be performed for qualitative analysis and quantitative analysis of the chemical composition of a member constituting a semiconductor device and a semiconductor memory device. The thickness of the member constituting the semiconductor device, the distance between members, and the like may be measured with a transmission electron microscope (TEM), for example.

### First Embodiment

According to a first embodiment, a semiconductor device includes an oxide semiconductor layer including indium (In), aluminum (Al), and zinc (Zn), the oxide semiconductor layer having an atomic ratio of the aluminum to a sum of indium, aluminum, and zinc of equal to or more than 8% and equal to or less than 23%, a gate electrode, and a gate insulating layer provided between the oxide semiconductor layer and the gate electrode.

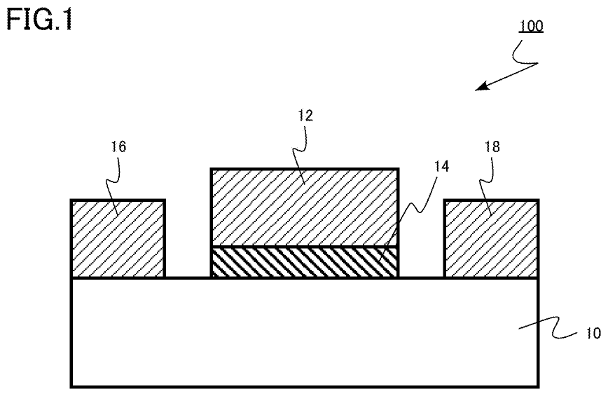

FIG. 1 is a schematic sectional view illustrating the semiconductor device in the first embodiment.

The semiconductor device in the first embodiment is a transistor 100. The transistor 100 is an oxide semiconductor transistor in which an oxide semiconductor is used for a channel layer.

The transistor 100 includes a channel layer 10 (oxide semiconductor layer), a gate electrode 12, a gate insulating layer 14, a source electrode 16, and a drain electrode 18.

The channel layer 10 is an example of the oxide semiconductor layer. In an ON operation of the transistor 100, a channel as a current path is formed in the channel layer 10.

The channel layer 10 includes an oxide semiconductor. The channel layer 10 includes a metal oxide. The channel layer 10 is amorphous, for example.

The channel layer 10 includes indium (In), aluminum (Al), and zinc (Zn). The atomic ratio of aluminum to the sum of indium, aluminum, and zinc in the channel layer 10 is equal to or more than 8% and equal to or less than 23%. That is, the atomic ratio represented by Al/(In+Al+Zn) is equal to or more than 8% and equal to or less than 23%.

The atomic ratio of the sum of indium, aluminum, and zinc among metal elements included in the channel layer 10 is equal to or more than 90%, for example. The atomic ratio of the sum of indium, aluminum, and zinc among elements other than oxygen included in the channel layer 10 is equal to or more than 90%, for example. For example, in the channel layer 10, an element which is an element other than oxygen and has an atomic ratio larger than an atomic ratio of any one of indium, aluminum, and zinc is not provided.

The atomic ratio of each of gallium (Ga), tin (Sn), and titanium (Ti) among the metal elements included in the channel layer 10 is less than 10%, for example.

The atomic ratio of indium to the sum of indium, aluminum, and zinc included in the channel layer 10 is equal to or more than 39% and equal to or less than 70%, for example. That is, the atomic ratio represented by In (In+Al+Zn) is equal to or more than 39% and equal to or less than 70%.

The thickness of the channel layer is equal to or more than 10 nm and equal to or less than 100 nm, for example.

The channel layer 10 is formed, for example, by an atomic layer deposition method (ALD method).

The gate electrode 12 includes, for example, metal, a metal compound, or a semiconductor. The gate electrode 12 includes, for example, tungsten (W). The gate length of the gate electrode 12 is equal to or more than 20 nm and equal to or less than 100 nm, for example.

The gate insulating layer 14 is provided between the channel layer 10 and the gate electrode 12. The gate insulating layer 14 includes, for example, an oxide or an oxynitride. The gate insulating layer 14 includes, for example, silicon oxide or aluminum oxide. The thickness of the gate insulating layer 14 is equal to or more than 2 nm and equal to or less than 10 nm, for example.

The source electrode 16 includes, for example, metal, a metal compound, a semiconductor, or a conductive oxide. The source electrode 16 may have a stacked structure with two or more kinds of materials. The source electrode 16 has a stacked structure with metal and a conductive oxide, for example. The source electrode 16 has a stacked structure with tungsten (W) and indium tin oxide, for example. For example, the surface of the source electrode 16 on the channel layer 10 side includes indium tin oxide.

The drain electrode 18 includes, for example, metal, a metal compound, a semiconductor, or a conductive oxide. The drain electrode 18 may have a stacked structure with two or more kinds of materials. The drain electrode 18 has a stacked structure with metal and a conductive oxide, for example. The drain electrode 18 has a stacked structure with tungsten (W) and indium tin oxide (ITO), for example. For example, the surface of the drain electrode 18 on the channel layer 10 side includes indium tin oxide.

An oxide layer (not illustrated) having a material different from the material of the gate insulating layer 14 may be provided between the channel layer 10 and the gate insulating layer 14. The oxide layer (not illustrated) has a chemical composition different from a chemical composition of the gate insulating layer 14

The functions and effects of the semiconductor device in the first embodiment will be described below.

When a memory cell using the oxide semiconductor transistor is formed, for example, contact resistance of a wiring layer connecting a capacitor and the transistor is reduced by applying heat treatment after the capacitor and the oxide semiconductor transistor are formed. Since the contact resistance is reduced, parasitic resistance in the memory cell is reduced, and loss of charges accumulated in the capacitor is reduced. The heat treatment is performed, for example, at a temperature which is equal to or higher than 420° C.

However, for example, a threshold voltage may fluctuate by applying the heat treatment after the oxide semiconductor transistor is formed. It is considered that the fluctuation of the threshold voltage occurs by dissociation of oxygen in a metal oxide forming the channel layer from the metal element. In other words, it is considered that oxygen vacancies are formed in the metal oxide forming the channel layer, and thus the threshold voltage fluctuates. It is expected to realize an oxide semiconductor transistor which has high heat resistance and small fluctuation in characteristics even after the heat treatment.

The heat resistance of an oxide semiconductor which is used for the channel layer 10 of the transistor 100 in the first embodiment and includes indium (In), aluminum (Al), and zinc (Zn) is higher than, for example, the heat resistance of an oxide semiconductor including indium (In), gallium (Ga), and zinc (Zn). The reason of higher heat resistance is considered as follows. That is, a formation energy of an oxygen vacancy increases by changing the metal element constituting the oxide semiconductor from gallium to aluminum. It is considered that, since the formation energy of the oxygen vacancy is high, the oxygen vacancy is formed less after the heat treatment, and the threshold voltage has difficulty in fluctuation.

In the oxide semiconductor including indium (In), aluminum (Al), and zinc (Zn), it is considered that the reason of the high formation energy of the oxygen vacancy is that a bonding force between aluminum and oxygen is large. Thus, it is considered that, if a ratio of aluminum in the oxide semiconductor is reduced, the oxygen vacancy is easily formed, and the heat resistance is reduced.

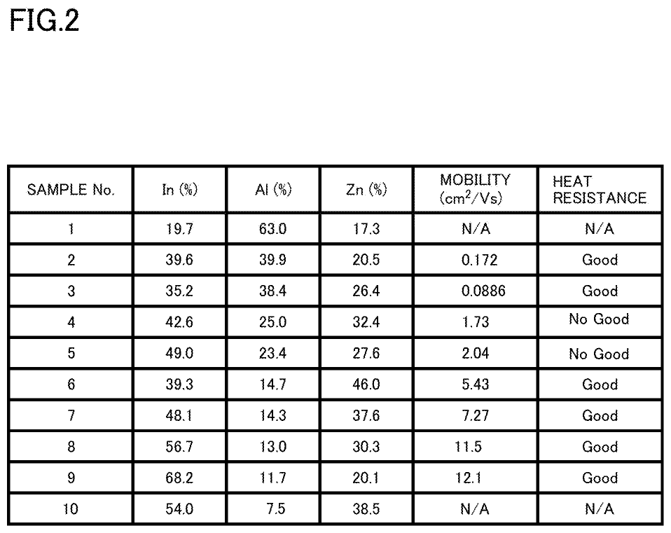

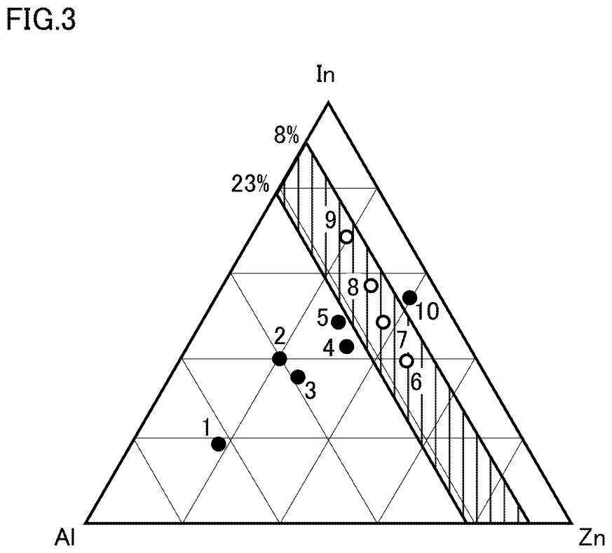

FIGS. 2 and 3 are diagrams illustrating the functions and effects of the semiconductor device in the first embodiment. FIG. 2 is a table illustrating evaluation results of mobility and the heat resistance of the oxide semiconductor transistor. An oxide semiconductor including indium (In), aluminum (Al), and zinc (Zn) was used for the channel layer, and the atomic ratios of indium, aluminum, and zinc were changed to evaluate mobility and the heat resistance of a transistor.

The atomic ratio of each of indium, aluminum, and zinc indicates the ratio of each metal element to the sum of indium, aluminum, and zinc. The heat resistance was evaluated using, as an index, fluctuation in threshold value after heat treatment was performed at 420° C. after the transistor was formed. A favorable case where the threshold voltage was secured to a positive voltage after the heat treatment was set as “Good”. A not-preferable case where, after heat treatment, the threshold voltage fluctuated to become a negative voltage was set as “No Good”.

In a case of Sample 1, transistor characteristics were not obtained, and thus the mobility and the heat resistance were set to “N/A (Not Applicable)”. In a case of Sample 10, the transistor maintains a depletion type before and after the heat treatment, and thus mobility and heat resistance were set to “N/A”.

FIG. 3 is a triangular diagram illustrating the compositions of the oxide semiconductors of Samples 1 to 10. The number attached to each circle indicates a sample number. The hatched region in FIG. 3 refers to a region in which the atomic ratio of aluminum to the sum of indium, aluminum, and zinc is equal to or more than 8% and equal to or less than 23%, that is, a region in which the atomic ratio represented by Al/(In+Al+Zn) is equal to or more than 8% and equal to or less than 23%.

Samples 6 to 9 included in the hatched region in FIG. 3 are indicated by white circles, and the other samples are indicated by black circles.

As clear from FIG. 2, the mobility increases as the atomic ratio of aluminum to the sum of indium, aluminum, and zinc is reduced. As clear from FIG. 2, regarding reduction in the atomic ratio of aluminum to the sum of indium, aluminum, and zinc is reduced, the heat resistance decreases when the atomic ratio of aluminum is around 24%, but the heat resistance increases when the atomic ratio of aluminum is reduced from 24%.

In Samples 6 to 9 in the region in which the atomic ratio of aluminum to the sum of indium, aluminum, and zinc is equal to or more than 8% and equal to or less than 23%, high mobility worthy of practical use can be realized. The mobility of the Samples 6 to 9 are equal to or greater than 5 cm² /Vs. Samples 6 to 9 have favorable heat resistance.

Thus, if the atomic ratio of aluminum to the sum of indium, aluminum, and zinc is equal to or more than 8% and equal to or less than 23%, the oxide semiconductor transistor 100 having high mobility and high heat resistance is realized.

It is considered that the reason that the mobility is improved as the atomic ratio of aluminum to the sum of indium, aluminum, and zinc is reduced is that the amount of oxygen vacancy functioning as a donor in the oxide semiconductor increases.

As described above, it is predicted that, if the ratio of aluminum in the oxide semiconductor is reduced, the oxygen vacancy is easily formed by the heat treatment, and the heat resistance is reduced. However, the inventors have found a unique region in which the heat resistance does not decrease but increases even though the ratio of aluminum in the oxide semiconductor decreases.

The reason of the unique region appearing is considered to be as follows. If the atomic ratio of aluminum is reduced, a ratio of a metal element having a large bonding force to oxygen is reduced, and thus the amount of the oxygen vacancy tends to increase by the heat treatment. However, it is considered that, when the ratio of aluminum is in a specific range, an oxygen vacancy structure formed is filled with aluminum, and thus the amount of the oxygen vacancy is decreased, during the heat treatment. That is, it is considered that, in the region in which the atomic ratio of aluminum is equal to or more than 3% and equal to or less than 23%, the oxygen vacancy is easily filled with aluminum during the heat treatment, and thus the increase of the oxygen vacancy is suppressed, and the heat resistance is not decreased.

It is considered that, in the region in which the atomic ratio of aluminum is more than 23%, filing the oxygen vacancy has difficulty by an interaction of aluminum atoms themselves, and thus the amount of the oxygen vacancy tends to increase with the atomic ratio of aluminum decreasing. It is considered that, if the atomic ratio of aluminum is smaller than 3%, the amount of aluminum for filling the oxygen vacancy is deficient, and thus the amount of the oxygen vacancy tends to increase with the atomic ratio of aluminum decreasing.

From a viewpoint of increasing the heat resistance of the transistor 100, the atomic ratio of aluminum to the sum of indium, aluminum, and zinc in the channel layer 10 is preferably equal to or more than 10% and equal to or less than 20%, and more preferably equal to or more than 11% and equal to or less than 15%.

From a viewpoint of increasing the heat resistance of the transistor 100, the atomic ratio of the sum of indium, aluminum, and zinc among the metal elements included in the channel layer 10 is preferably equal to or more than 90%, and more preferably equal to or more than 95%, for example.

From a viewpoint of increasing the heat resistance of the transistor 100, the atomic ratio of each of gallium (Ga), tin (Sn), and titanium (Ti) among the metal element included in the channel layer 10 is preferably smaller than 10%, and more preferably smaller than 5%.

From a viewpoint of increasing the heat resistance of the transistor 100, the atomic ratio of indium to the sum of indium, aluminum, and zinc included in the channel layer 10 is preferably equal to or more than 39%.

From a viewpoint of stabilizing the characteristics of the transistor 100, it is preferable that the channel layer 10 is amorphous, not crystallized. From a viewpoint of suppressing crystallization of the channel layer 10 and stabilizing the characteristics of the transistor 100, the atomic ratio of indium to the sum of indium, aluminum, and zinc included in the channel layer 10 is preferably equal to or smaller than 70%.

As above described, according to the first embodiment, the oxide semiconductor transistor 100 having high mobility and high heat resistance is realized.

### Second Embodiment

According to a second embodiment, a semiconductor device includes a first electrode, a second electrode, an oxide semiconductor layer provided between the first electrode and the second electrode, the oxide semiconductor layer including indium (In), aluminum (Al), and zinc (Zn), and the oxide semiconductor layer having an atomic ratio of aluminum to a sum of indium, aluminum, and zinc of equal to or more than 8% and equal to or less than 23%, a gate electrode surrounding the oxide semiconductor layer, and a gate insulating layer provided between the oxide semiconductor layer and the gate electrode. The semiconductor device in the second embodiment is different from the semiconductor device in the first embodiment in that the gate electrode surrounds the oxide semiconductor layer. Some descriptions of contents overlapping those in the first embodiment may be omitted below.

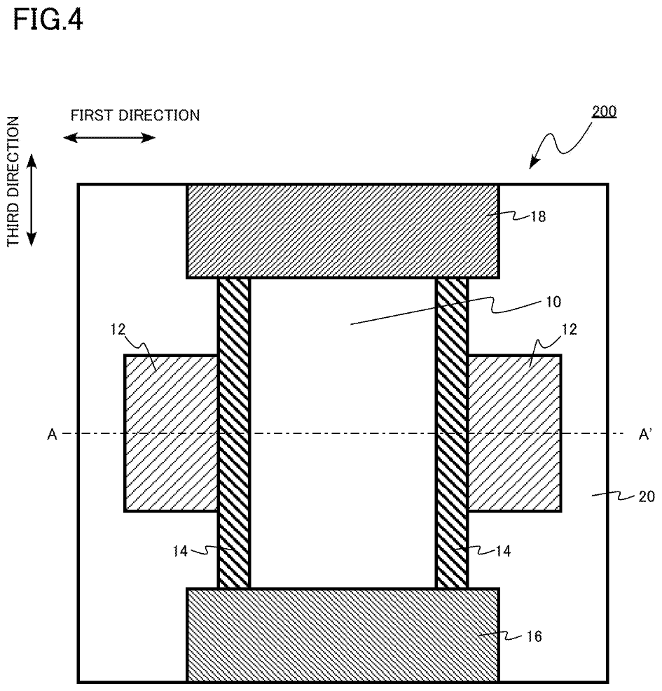

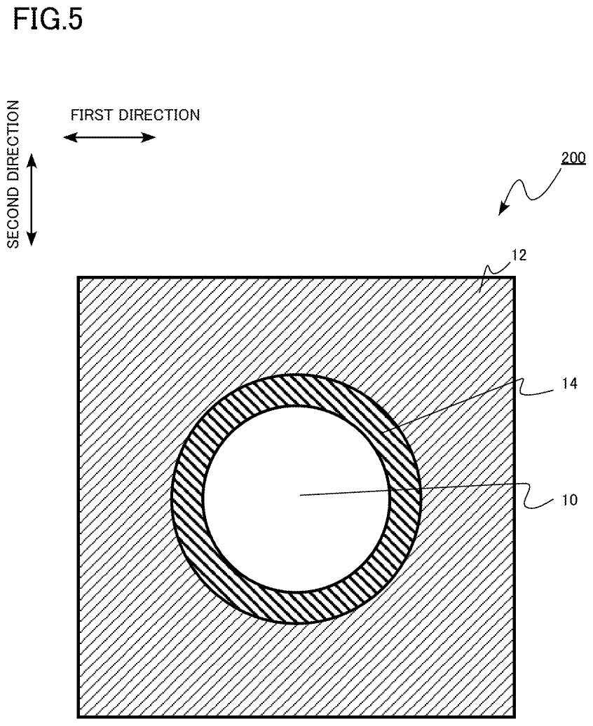

FIGS. 4 and 5 are schematic sectional views illustrating the semiconductor device in the second embodiment. FIG. 5 is a sectional view taken along line AA′ in FIG. 4. In FIG. 4, a horizontal direction is referred to as a first direction, a depth direction is referred to as a second direction, and a vertical direction is referred to as a third direction.

The semiconductor device in the second embodiment is a transistor 200. The transistor 200 is an oxide semiconductor transistor in which an oxide semiconductor is used for a channel layer. The transistor 200 is a so-called surrounding gate transistor (SGT) in which a gate electrode is provided to surround a channel layer. The transistor 200 is a so-called vertical transistor.

The transistor 200 includes a channel layer 10 (oxide semiconductor layer), a gate electrode 12, a gate insulating layer 14, a source electrode 16 (first electrode), a drain electrode 18 (second electrode), and an interlayer insulating layer 20.

The source electrode 16 is an example of the first electrode. The source electrode 16 includes, for example, metal, a metal compound, a semiconductor, or a conductive oxide. The source electrode 16 may have a stacked structure with two or more kinds of materials. The source electrode 16 has a stacked structure with metal and a conductive oxide, for example. The source electrode 16 has a stacked structure with tungsten (W) and indium tin oxide (ITO), for example. For example, the surface of the source electrode 16 on the channel layer 10 side includes indium tin oxide.

The drain electrode 18 is an example of the second electrode. The drain electrode 18 includes, for example, metal, a metal compound, a semiconductor, or a conductive oxide. The drain electrode 18 may have a stacked structure with two or more kinds of materials. The drain electrode 18 has a stacked structure with metal and a conductive oxide, for example. The drain electrode 18 has a stacked structure with tungsten (W) and indium tin oxide (ITO), for example. For example, the surface of the drain electrode 18 on the channel layer 10 side includes indium tin oxide.

The channel layer 10 is provided between the source electrode 16 and the drain electrode 18. The channel layer 10 is an example of the oxide semiconductor layer. In the ON operation of the transistor 200, a channel as a current path is formed in the channel layer 10. The channel layer 10 extends in the third direction. The channel layer 10 has a columnar shape extending in the third direction. The channel layer 10 has a cylindrical shape, for example.

The channel layer 10 includes an oxide semiconductor. The channel layer 10 includes a metal oxide. The channel layer 10 is amorphous, for example.

The channel layer 10 includes indium (In), aluminum (Al), and zinc (Zn). The atomic ratio of aluminum to the sum of indium, aluminum, and zinc in the channel layer 10 is equal to or more than 8% and equal to or less than 23%. That is, the atomic ratio represented by Al/(In+Al+Zn) is equal to or more than 8% and equal to or less than 23%.

The width of the channel layer in the first direction is equal to or more than 20 nm and equal to or less than 100 nm, for example.

The gate electrode 12 includes, for example, metal, a metal compound, or a semiconductor. The gate electrode 12 includes, for example, tungsten (W). The gate length of the gate electrode 12 is equal to or more than 20 nm and equal to or less than 100 nm, for example.

The gate electrode 12 is provided to surround the channel layer 10. The gate electrode 12 is provided around the channel layer 10.

The gate electrode 12 includes, for example, metal, a metal compound, or a semiconductor. The gate electrode 12 includes, for example, tungsten.

The gate length (width in the third direction) of the gate electrode 12 is equal to or more than 20 nm and equal to or less than 100 nm, for example.

The gate insulating layer 14 is provided between the channel layer 10 and the gate electrode 12. The gate insulating layer 14 is provided to surround the channel layer 10. The gate insulating layer 14 includes, for example, an oxide or an oxynitride. The gate insulating layer 14 includes, for example, silicon oxide or aluminum oxide. The thickness of the gate insulating layer 14 is equal to or more than 2 nm and equal to or less than 10 nm, for example.

The interlayer insulating layer 20 is provided, for example, between the source electrode 16 and the gate electrode 12, and between the drain electrode 18 and the gate electrode 12. The interlayer insulating layer 20 electrically isolates the source electrode 16, the drain electrode 18, and the gate electrode 12 from each other. The interlayer insulating layer 20 includes, for example, an oxide. The interlayer insulating layer 20 includes, for example, silicon oxide.

As above described, according to the second embodiment, similar to the first embodiment, the oxide semiconductor transistor 200 having high mobility and high heat resistance is realized. According to the second embodiment, since the transistor is an SGT, it is possible to dispose the transistor with high density per unit area.

### Third Embodiment

A semiconductor device according to a third embodiment is different from the semiconductor device in the second embodiment in that the semiconductor device in the third embodiment includes a first oxide layer provided between the oxide semiconductor layer and the gate insulating layer, the first oxide layer having a material different from materials of the oxide semiconductor layer and the gate insulating layer, and a second oxide layer provided between at least any one of the first electrode and the second electrode, and the oxide semiconductor layer, the second oxide layer having a material different from the materials of the oxide semiconductor layer. Some descriptions of contents overlapping those in the first and second embodiments may be omitted below.

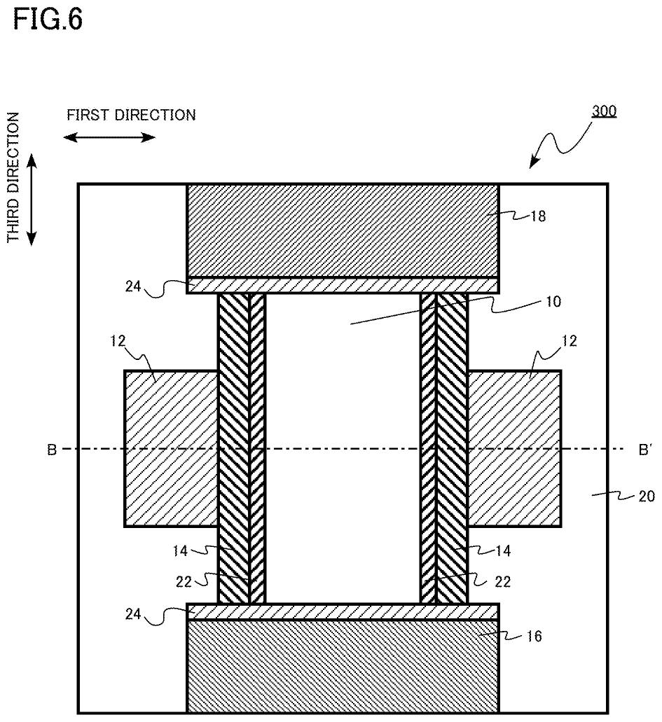

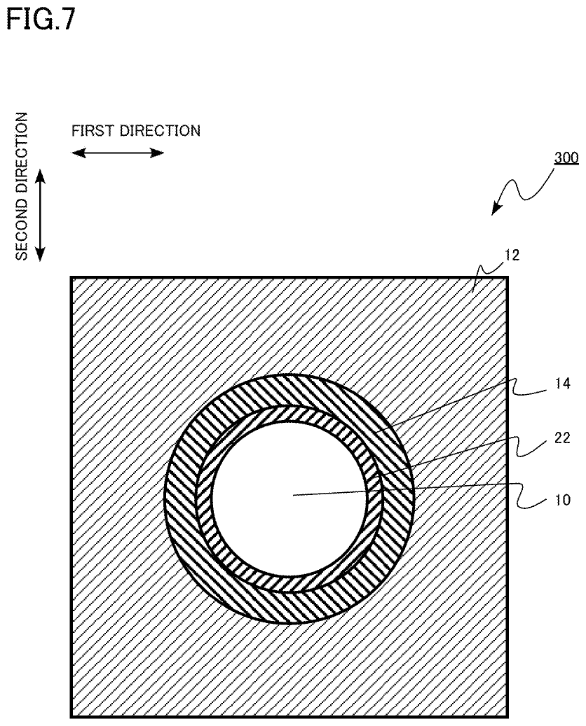

FIGS. 6 and 7 are schematic sectional views illustrating the semiconductor device in the third embodiment. FIG. 7 is a sectional view taken along line BB′ in FIG. 6. In FIG. 6, the horizontal direction is referred to as the first direction, the depth direction is referred to as the second direction, and the vertical direction is referred to as the third direction.

The semiconductor device in the third embodiment is a transistor 300. The transistor 300 is an oxide semiconductor transistor in which an oxide semiconductor is used for a channel layer. The transistor 300 is a so-called SGT in which the gate electrode is provided to surround the channel layer. The transistor 300 is a so-called vertical transistor.

The transistor 300 includes a channel layer 10 (oxide semiconductor layer), a gate electrode 12, a gate insulating layer 14, a source electrode 16 (first electrode), a drain electrode 18 (second electrode), an interlayer insulating layer 20, a first oxide layer 22, and a second oxide layer 24.

The first oxide layer 22 is provided between the channel layer 10 and the gate insulating layer 14. The first oxide layer 22 is formed of a material different from the materials of the channel layer 10 and the gate insulating layer 14. The first oxide layer 22 has a chemical composition different from chemical compositions of the channel layer 10 and the gate insulating layer 14.

The first oxide layer 22 is formed of a metal oxide, for example. For example, gallium oxide, aluminum oxide, hafnium oxide, or indium gallium oxide containing silicon may be used for the first oxide layer 22.

Since the first oxide layer 22 is provided, for example, mobility of carriers increases, and the characteristics of the transistor 300 are improved.

The second oxide layer 24 is provided between the source electrode 16 and the channel layer 10, and between the drain electrode 18 and the channel layer 10. The second oxide layer 24 is formed of a material different from the materials of the channel layer 10. The second oxide layer 24 has a chemical composition different from a chemical composition of the channel layer 10. The second oxide layer 24 may be formed of the same material as the material of the first oxide layer 22.

The second oxide layer 24 has a function of reducing resistance between the source electrode 16 and the channel layer 10, and between the drain electrode 18 and the channel layer 10.

The second oxide layer 24 is formed of a metal oxide, for example. For example, oxides in which zinc (Zn), aluminum (Al), tin (Sn), indium (In), or the like is contained in gallium oxide, indium oxide, and gallium oxide may be applied for the second oxide layer 24.

Since the second oxide layer 24 is provided, for example, on-resistance of the transistor 300 having reduced parasitic resistance is reduced.

The second oxide layer 24 is provided in only any one of a space between the source electrode 16 and the channel layer 10, and a space between the drain electrode 18 and the channel layer 10. A configuration in which only any one of the first oxide layer 22 and the second oxide layer 24 is provided may be made.

As above described, according to the third embodiment, similar to the first embodiment, the oxide semiconductor transistor 300 having high mobility and high heat resistance is realized. Similar to the second embodiment, since the transistor is an SGT, it is possible to dispose the transistor with high density per unit area. Since the first oxide layer 22 and the second oxide layer 24 are provided, the transistor 300 having further improved characteristics is realized.

### Fourth Embodiment

According to a fourth embodiment, a semiconductor memory device includes a first wiring extending in a first direction, a second wiring provided on one side of the first wiring, the second wiring extending in a second direction intersecting with the first direction, a third wiring provided on the other side of the first wiring, the third wiring extending in the second direction, a first memory cell provided on the one side, and a second memory cell provided on the other side. Each of the first memory cell and the second memory cell includes an oxide semiconductor layer including indium (In), aluminum (Al), and zinc (Zn), the oxide semiconductor layer having an atomic ratio of aluminum to a sum of indium, aluminum, and zinc of equal to or more than 8% and equal to or less than 23%, a gate electrode surrounding the oxide semiconductor layer, a gate insulating layer provided between the oxide semiconductor layer and the gate electrode, and a capacitor electrically connected to one end of the oxide semiconductor layer. The first wiring is electrically connected to the other end of the oxide semiconductor layer in the first memory cell. The first wiring is electrically connected to the other end of the oxide semiconductor layer in the second memory cell. The second wiring is electrically connected to the gate electrode in the first memory cell. The third wiring is electrically connected to the gate electrode in the second memory cell. The first memory cell and the second memory cell include the capacitor electrically connected to one end of the oxide semiconductor layer in the semiconductor device in the second embodiment. Some descriptions of contents overlapping those in the first to third embodiments may be omitted below.

A semiconductor memory device in the fourth embodiment is a semiconductor memory 400. The semiconductor memory device in the fourth embodiment is a dynamic random access memory (DRAM). In the semiconductor memory 400, the transistor 200 in the second embodiment is used as a switching transistor of a memory cell in the DRAM.

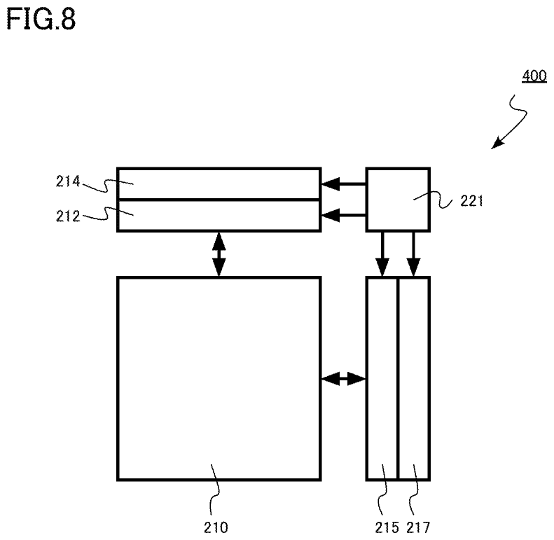

FIG. 8 is a block diagram illustrating the semiconductor memory device in the fourth embodiment.

As illustrated in FIG. 8, the semiconductor memory 400 includes a memory cell array 210, a word line driver circuit 212, a row decoder circuit 214, a sense amplifier circuit 215, a column decoder circuit 217, and a control circuit 221.

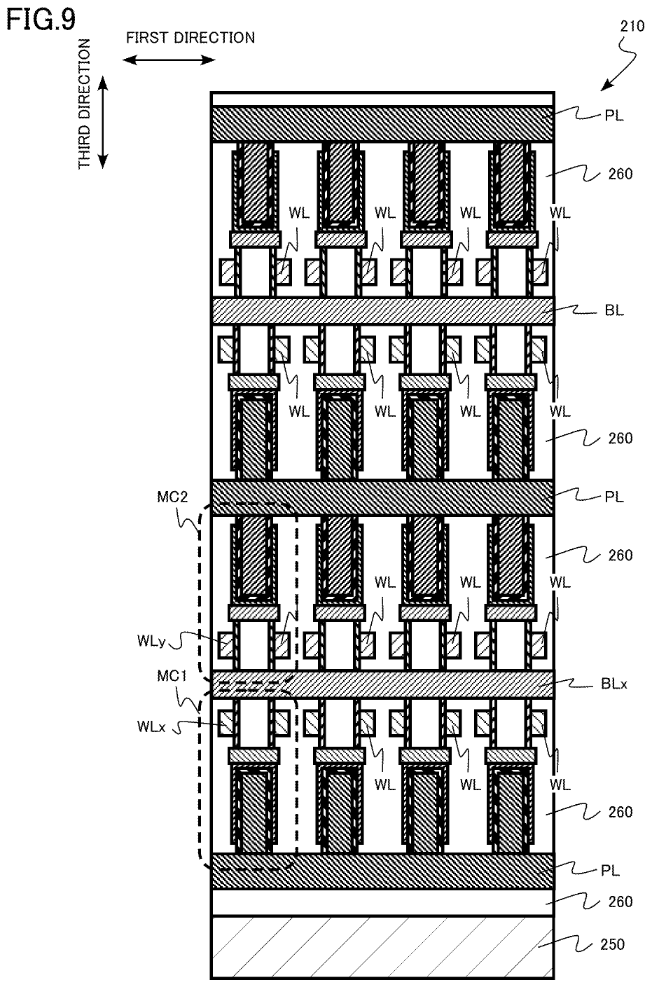

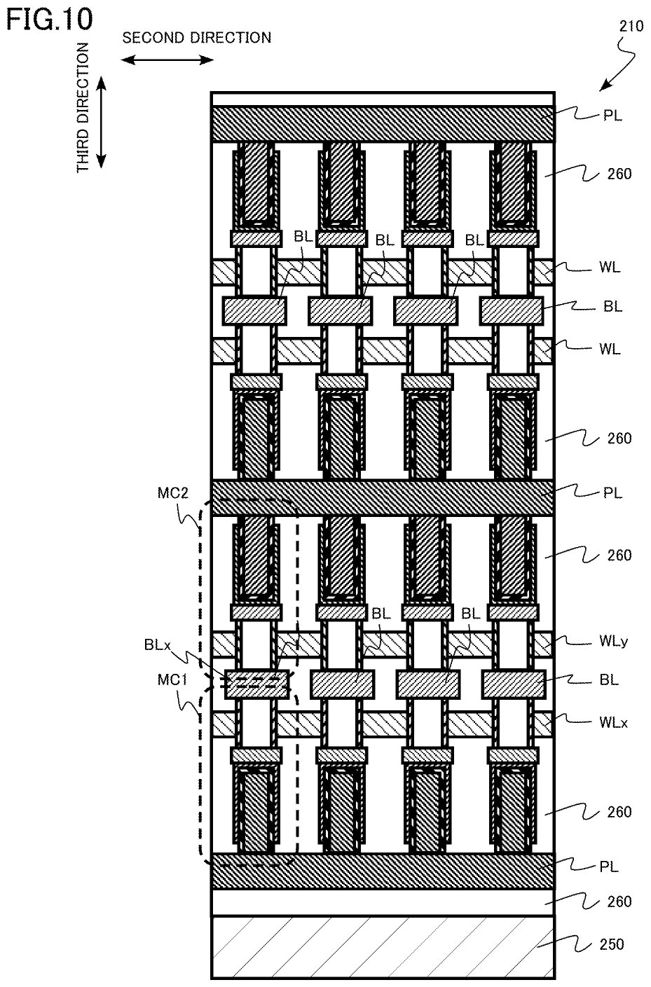

FIGS. 9 and 10 are schematic sectional views illustrating a memory cell array in the semiconductor memory device in the fourth embodiment. FIG. 9 is a sectional view taken along a plane including the first direction and the third direction. FIG. 10 is a sectional view taken along a plane including the second direction and the third direction. The first direction intersects with the second direction. The first direction is perpendicular to the second direction, for example. The third direction is perpendicular to the first direction and the second direction. The third direction is perpendicular to a substrate, for example.

In the fourth embodiment, the memory cell array 210 includes a three-dimensional structure in which memory cells are three-dimensionally disposed. In FIGS. 9 and 10, a region surrounded by a broken line indicates one memory cell.

The memory cell array 210 includes a silicon substrate 250 (substrate). The memory cell array 210 includes, for example, a plurality of bit lines BL and a plurality of word lines WL on the silicon substrate 250.

The bit line BL extends in the first direction. The word line WL extends in the second direction.

The bit line BL and the word line WL vertically intersect with each other, for example. A memory cell is disposed in a region in which the bit line BL and the word line WL intersect with each other. The memory cell includes a first memory cell MC1 and a second memory cell MC2.

A bit line BL connected to the first memory cell MC1 and the second memory cell MC2 is a bit line BLx (first wiring). A word line WL connected to the first memory cell MC1 is a word line WLx (second wiring). A word line WL connected to the second memory cell MC2 is a word line (third wiring) WLy. The word line WLx (second wiring) is provided on one side of the bit line BLx (first wiring).

The word line WLy (third wiring) is provided on the other side of the bit line BLx (first wiring).

The memory cell array 210 includes a plurality of plate electrode lines PL. The plate electrode line PL is connected to a plate electrode in each memory cell.

The memory cell array 210 includes an interlayer insulating layer 260 for electrical isolation between wirings and electrodes.

The plurality of word lines WL are electrically connected to the row decoder circuit 214. The plurality of bit lines BL are electrically connected to the sense amplifier circuit 215.

The row decoder circuit 214 has a function of selecting the word line WL in accordance with an input row address signal. The word line driver circuit 212 has a function of applying a predetermined voltage to the word line WL selected by the row decoder circuit 214.

The column decoder circuit 217 has a function of selecting the bit line BL in accordance with an input column address signal. The sense amplifier circuit 215 has a function of applying a predetermined voltage to the bit line BL selected by the column decoder circuit 217. The sense amplifier circuit 215 has a function of detecting and amplifying the potential of the bit line BL.

The control circuit 221 has a function of controlling the word line driver circuit 212, the row decoder circuit 214, the sense amplifier circuit 215, the column decoder circuit 217, and other circuits (not illustrated).

The circuits such as the word line driver circuit 212, the row decoder circuit 214, the sense amplifier circuit 215, the column decoder circuit 217, and the control circuit 221 are configured by transistors and wiring layers which are not illustrated and are formed using the silicon substrate 250, for example.

The bit line BL and the word line WL are metal, for example. Each of the bit line EL and the word line WL is titanium nitride, tungsten, or has a stacked structure with titanium nitride and tungsten, for example.

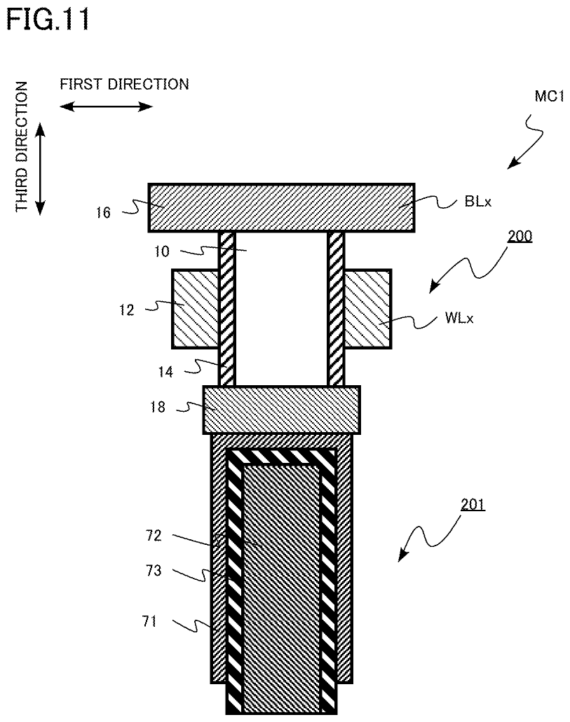

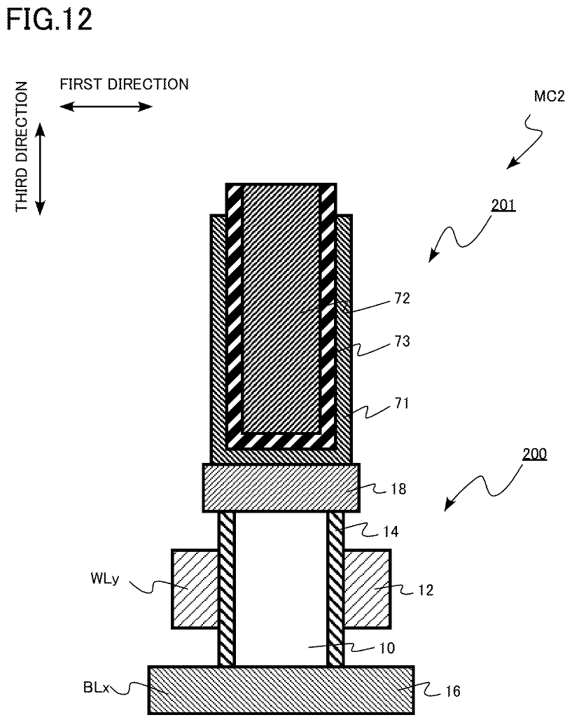

FIG. 11 is a schematic sectional view illustrating the first memory cell in the semiconductor memory device in the fourth embodiment. FIG. 12 is a schematic sectional view illustrating the second memory cell in the semiconductor memory device in the fourth embodiment.

The first memory cell MC1 is provided between the silicon substrate 250 and the bit line BLx (first wiring). The bit line BLx (first wiring) is provided between the silicon substrate 250 and the second memory cell MC2. The first memory cell MC1 is provided on one side of the bit line BLx (first wiring). The second memory cell MC2 is provided on the other side of the bit line BLx (first wiring).

The second memory cell MC2 has a structure in which the first memory cell MC1 is inverted upside down. Each of the first memory cell MC1 and the second memory cell MC2 includes a transistor 200 and a capacitor 201.

The transistor 200 includes a channel layer 10 (oxide semiconductor layer), a gate electrode 12, a gate insulating layer 14, a source electrode 16 (first electrode), and a drain electrode 18 (second electrode). The transistor 200 has a configuration similar to the configuration of the transistor 200 in the second embodiment.

The channel layer 10 includes indium (In), aluminum (Al), and zinc (Zn). The atomic ratio of aluminum to the sum of indium, aluminum, and zinc in the channel layer 10 is equal to or more than 8% and equal to or less than 23%. That is, the atomic ratio represented by Al/(In+Al+Zn) is equal to or more than 8% and equal to or less than 23%.

The capacitor 201 includes a cell electrode 71, a plate electrode 72, and a capacitor insulating film 73. The cell electrode 71 and the plate electrode 72 include, for example, titanium oxide. The capacitor insulating film 73 has a stacked structure of zirconium oxide, aluminum oxide, and zirconium oxide, for example.

The capacitor 201 is connected to one end of the channel layer 10 of each of the first memory cell MC1 and the second memory cell MC2. The cell electrode 71 in the capacitor 201 is connected to the drain electrode 18. The plate electrode 72 is connected to the plate electrode line PL.

The source electrode 16 is connected to the bit line BL. The gate electrode 12 is connected to the word line WL.

FIGS. 9 to 12 illustrate, as an example, a case where the bit line BL and the source electrode 16, and the word line WL and the gate electrode 12 are simultaneously formed of the same material. The bit line BL and the source electrode 16, and the word line WL and the gate electrode 12 may be separately formed of different materials.

The bit line BLx (first wiring) is electrically connected to an end portion (the other end) of the channel layer 10 in the first memory cell MC1 on an opposite side of a side to which the capacitor 201 is connected. The bit line BLx (first wiring) is electrically connected to an end portion (the other end) of the channel layer 10 in the second memory cell MC2 on an opposite side of a side to which the capacitor 201 is connected.

The word line WLx (second wiring) is electrically connected to the gate electrode 12 of the first memory cell MC1. The word line WLy (third wiring) is electrically connected to the gate electrode 12 of the second memory cell MC2.

According to the fourth embodiment, a semiconductor memory having improved memory characteristics is realized by using the transistor 200 in the second embodiment as the switching transistor in the DRAM.

In the fourth embodiment, a case using the transistor 200 in the second embodiment as the switching transistor in the DRAM is described as an example. However, the transistor 300 in the third embodiment may be adopted instead of the transistor 200 in the second embodiment.

While certain embodiments have been described, these embodiments have been presented by way of example only, and are not intended to limit the scope of the inventions. Indeed, a semiconductor device and a semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
an oxide semiconductor layer including indium (In), aluminum (Al), and zinc (Zn), the oxide semiconductor layer having an atomic ratio of the aluminum to a sum of indium, aluminum, and zinc of equal to or more than 8% and equal to or less than 23%;
a gate electrode; and
a gate insulating layer provided between the oxide semiconductor layer and the gate electrode.

2. The semiconductor device according to claim 1,
wherein an atomic ratio of the sum of indium, aluminum, and zinc among metal elements included in the oxide semiconductor layer is equal to or more than 90%.

3. The semiconductor device according to claim 1,
wherein an atomic ratio of each of gallium (Ga), tin (Sn), and titanium (Ti) among metal elements included in the oxide semiconductor layer is less than 10%.

4. The semiconductor device according to claim
wherein an atomic ratio of indium to the sum of indium, aluminum, and zinc included in the oxide semiconductor layer is equal to or more than 39%.

5. The semiconductor device according to claim 1,
wherein an atomic ratio of indium to the sum of indium, aluminum, and zinc included in the oxide semiconductor layer is equal to or less than 70%.

6. A semiconductor device comprising:
a first electrode;
a second electrode;
an oxide semiconductor layer provided between the first electrode and the second electrode, the oxide semiconductor layer including indium (In), aluminum (Al), and zinc (Zn), the oxide semiconductor layer having an atomic ratio of aluminum to a sum of indium, aluminum, and zinc of equal to or more than 8% and equal to or less than 23%;
a gate electrode surrounding the oxide semiconductor layer; and
a gate insulating layer provided between the oxide semiconductor layer and the gate electrode.

7. The semiconductor device according to claim 6,
wherein an atomic ratio of the sum of indium, aluminum, and zinc among metal elements included in the oxide semiconductor layer is equal to or more than 90%.

8. The semiconductor device according to claim 6,
wherein an atomic ratio of each of gallium (Ga), tin (Sn), and titanium (Ti) included in the oxide semiconductor layer is less than 10%.

9. The semiconductor device according to claim 6,
wherein an atomic ratio of indium to the sum of indium, aluminum, and zinc included in the oxide semiconductor layer is equal to or more than 39%.

10. The semiconductor device according to claim 6,
wherein an atomic ratio of indium to the sum of indium, aluminum, and zinc included in the oxide semiconductor layer is equal to or less than 70%.

11. The semiconductor device according to claim 6, further comprising:
a first oxide layer provided between the oxide semiconductor layer and the gate insulating layer, the first oxide layer having a material different from materials of the oxide semiconductor layer and the gate insulating layer.

12. The semiconductor device according to claim 6, further comprising:
a second oxide layer provided between at least one of the first electrode and the second electrode, and the oxide semiconductor layer, the second oxide layer having a material different from materials of the oxide semiconductor laver.

13. The semiconductor device according to claim 6, further comprising:
a capacitor electrically connected to one of the first electrode and the second electrode.

14. A semiconductor memory device comprising:
a first wiring extending in a first direction;
a second wiring provided on one side of the first wiring, the second wiring extending in a second direction intersecting with the first direction;
a third wiring provided on an other side of the first wiring, the third wiring extending in the second direction;
a first memory cell provided on the one side; and
a second memory cell provided on the other side,
wherein each of the first memory cell and the second memory cell includes
an oxide semiconductor layer including indium (In), aluminum (Al), and zinc (Zn), the oxide semiconductor layer having an atomic ratio of aluminum to a sum of indium, aluminum, and zinc of equal to or more than 8% and equal to or less than 23%,
a gate electrode surrounding the oxide semiconductor layer,
a gate insulating layer provided between the oxide semiconductor layer and the gate electrode, and
a capacitor electrically connected to one end of the oxide semiconductor layer,
the first wiring is electrically connected to an other end of the oxide semiconductor layer in the first memory cell,
the first wiring is electrically connected to an other end of the oxide semiconductor layer in the second memory cell,
the second wiring is electrically connected to the gate electrode in the first memory cell, and
the third wiring is electrically connected to the gate electrode in the second memory cell.

15. The semiconductor memory device according to claim 14,
wherein an atomic ratio of the sum of indium, aluminum, and zinc among metal elements included in the oxide semiconductor layer is equal to or more than 90%.

16. The semiconductor memory device according to claim 14,
wherein an atomic ratio of each of gallium (Ga), tin (Sn), and titanium (Ti) included in the oxide semiconductor layer is less than 10%.

17. The semiconductor memory device according to claim 14,
wherein an atomic ratio of indium to the sum of indium, aluminum, and zinc included in the oxide semiconductor layer is equal to or more than 39%.

18. The semiconductor memory device according to claim 14,
wherein an atomic ratio of indium to the sum of indium, aluminum, and zinc included in the oxide semiconductor layer is equal to or less than 70%.
